(19) United States
(12) Patent Application Publication
(10) Pub. No.: US 2015/0016926 A1
(43) Pub. Date: Jan. 15, 2015

(54) POD HAVING TOP COVER APERTURE FOR DETECTING SURROUNDING GAS WITHIN THE POD

(71) Applicant: TEXAS INSTRUMENTS INCORPORATED, Dallas, TX (US)

(72) Inventor: Young Sawk Oh, Dallas, TX (US)

(73) Assignee: TEXAS INSTRUMENTS INCORPORATED, Dallas, TX (US)

(21) Appl. No.: 14/504,631

(22) Filed: Oct. 2, 2014

Related U.S. Application Data
(62) Division of application No. 13/346,882, filed on Jan. 10, 2012.

(51) Int. Cl. H01L 21/673

(52) U.S. Cl. CPC H01L 21/67389
USPC 414/217

(57) ABSTRACT

A storage Pod for semiconductor substrates includes a top cover formed from a non-air permeable (NAP) material having faces including a top and a plurality of sides. A bottom base plate has a locking structure configured for providing a locking position for locking the sides, and for providing an unlocked position where the sides are detached from the bottom base plate. The top cover includes at least one aperture in the NAP material for allowing surrounding gases in an environment around the storage Pod to flow into the storage Pod to permit a gas sensor within the storage Pod to sense the target gas.

### FIELD

This Application is a Divisional of prior application Ser. No. 13/346,882, filed Jan. 10, 2012, currently pending.

This disclosure relates to monitoring the contamination in a cleanroom involved in fabrication processes of semiconductor substrates, such as wafers.

### BACKGROUND

Standardized Mechanical InterFace (SMIF) technology was developed to create mini clean environments for housing and transporting semiconductor substrates, such as silicon wafers. A SMIF pod is a container (usually made of an optically transparent plastic material such as polycarbonate) designed to accommodate wafers of a particular size in a wafer-storage cassette, which can be accessed by an operator or by automated mechanical interfaces from manufacturing tools that generally comprise robotic-based semiconductor production equipment. Each Pod has a number of standard recognition points such as coupling plates, pins, holes and/or electronic tags that can be recognized by operators or robotic machinery.

A conventional SMIF Pod protects the wafers during some front-end wafer fabrication processes by isolating the wafers from contamination by providing a mini environment with controlled airflow, pressure and particle count. The wafers therefore remain in a carefully controlled environment whether in the SMIF pod or in a manufacturing tool, without being exposed to the surrounding airflow in the environment around the Pod.

A SMIF Pod has a bottom-opening “door” so that when a SMIF pod is placed on a port on a manufacturing tool, the cassette containing the wafers can be lowered into the tool and the wafers removed by robotics. The SMIF Pod includes a cover that mates with the door to provide a sealed environment for the wafers within the cassette. SMIF Pods are typically used for wafer sizes of about 200 mm diameter or less wafers.

Larger wafers generally employ a Front Opening Unified Pod (FOUP). A FOUP has an access “door” located on a side that is perpendicular to horizontally stored wafers that can be used for 300 mm diameter wafers. Automated transfer systems for use with FOUPs are known. FOUPs are designed to be lifted and lowered by automated material handling systems (AMHS), such as overhead hoist transport (OHT) systems.

### SUMMARY

Disclosed embodiments recognize although the intention of conventional storage Pods for semiconductor substrates is to protect the semiconductor substrates from particulates and other sources of contamination such as gases in the environment surrounding the Pod, such storage Pods can be susceptible to airborne molecular contaminate (AMC) events because the Pod may not be fully hermetically (airtight) sealed. Therefore the AMC's potential impact on semiconductor substrate quality, and therefore die yield, has been overlooked.

Prior to disclosed Pods, such as when using coated wafers as gas sensors for AMC sensing (sometimes referred to as “witness wafers”), it was necessary to manually transfer the witness wafer in and out of the storage Pod to allow the witness wafer to have a direct exposure for a sufficient exposure time to the AMC in the cleanroom to provide the needed AMC-induced effect. This manual procedure is not manufacture-friendly as it involves both manual labor and time.

Disclosed Pods solve the problem of sensing AMCs including the environmental atmosphere conditions surrounding Pods by including at least one air permeable region comprising an aperture in the top cover of the Pod to allow sensing for AMCs inside the Pod, thus removing the need to remove the gas sensor from the Pod to expose the gas sensor to surrounding gases. The aperture(s) allows surrounding gases in an environment around the storage Pod to flow into the storage Pod and circulate inside the Pod to expose a gas sensor in the storage Pod to the surrounding gases. The gas sensor provides a response while in the Pod within an exposure time if the surrounding gases include the target gas. The gas sensor can comprise a coating that is sensitive to at least one target gas by generating a measurable response from exposure to a target gas, such as a witness wafer having a metal or metal alloy coating that is sensitive to one or more halogens. The presence of the target gas can be determined from a property of the gas sensor, such as an optical or electrical property.

### BRIEF DESCRIPTION OF THE DRAWINGS

FIG. 1 is a flow chart showing steps for a method of automatically sensing the presence of at least one target gas within a storage Pod having semiconductor substrates therein using a gas sensor sensitive to the target gas within the storage Pod, according to an example embodiment.

FIG. 2A is a depiction of a known storage Pod for semiconductor substrates comprising a solid top cover comprising a non-air permeable (NAP) material having faces including a top and a plurality of sides.

FIG. 2B is a depiction of a storage Pod for semiconductor substrates comprising a top cover comprising a NAP material having faces including a top and a plurality of sides shown, wherein there are a plurality of apertures in the NAP material of the top cover that allow surrounding gases in an environment around the storage Pod to flow into the storage Pod, according to an example embodiment.

FIG. 2C is depiction of a storage Pod for semiconductor substrates comprising a top cover comprising a NAP material having faces including a top and a plurality of sides, wherein there are a plurality of apertures in the NAP material of the top cover covered by a porous material for trapping particles that allows at least one target gas in surrounding gases in the environment around the storage Pod to flow into the storage Pod, according to an example embodiment.

FIG. 3 is a depiction of a gas detector system including a witness wafer having a sensor coating that can be used inside a disclosed storage Pod, according to example embodiments.

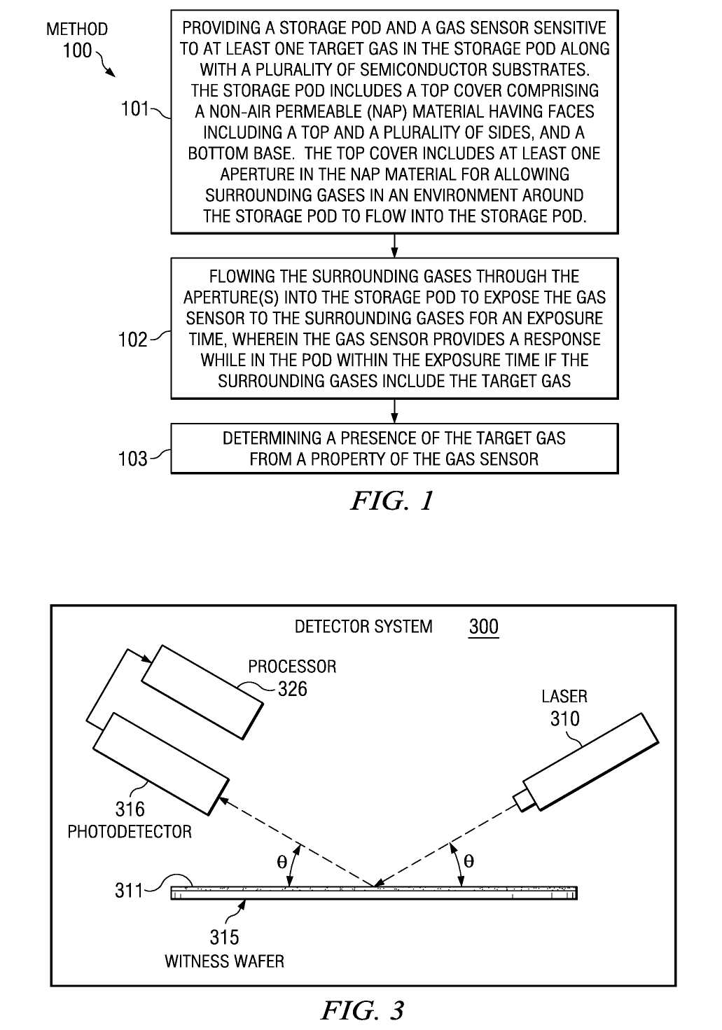

### DETAILED DESCRIPTION

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Disclosed embodiment include a method 100 of automatically sensing the presence of at least one target gas in surrounding gas from within a storage Pod having semiconductor substrates therein, according to an example embodiment. Method 100 is generally performed in a cleanroom used for semiconductor fabrication. As known in the art, a cleanroom provides a low level of environmental pollutants such as dust, airborne microbes, aerosol particles and chemical vapors.

Step 101 comprises providing a storage Pod and a gas sensor sensitive to at least one target gas within the storage Pod. The gas sensor can be part of a gas detector system that can be small enough so that the entire detector system including its battery can be fit within the storage Pod. A plurality of product substrates (e.g., product wafers) are within the storage Pod with the gas sensor, typically oriented horizontally within slots of a wafer cassette.

The storage Pod includes a top cover comprising a NAP material having faces including a top and a plurality of sides, a bottom base plate having a locking structure configured for providing a locking position where the plurality of sides of the top cover are locked to the bottom base plate, and for providing an unlocked position where the plurality of sides of the top cover are detached from the bottom base plate. The NAP material can comprise a polymer, such as polycarbonate which is a polymer that provides optical transparency.

The top cover includes at least one aperture in the NAP material for allowing surrounding gases in an environment around the storage Pod to flow into the storage Pod. In some embodiments there are a plurality of apertures, such as machined (e.g., drilled) perforations in the NAP. The Pod apertures also allow the air to circulate in the storage Pod to expose the gas senor in the Pod to the surrounding gases which is taught away by conventional logic in the wafer fab since as noted above storage Pods are designed to be hermetically sealed to keep all the surrounding gases in the cleanroom out of the Pod.

Disclosed gas permeable regions provide significantly more gas flow into the Pod as compared to Pods that may not be fully hermetically (airtight) sealed, such as due to manufacturing defects or wear on seals over time. As used herein, “flow into the storage pod” refers to the air comprising gas velocity from the atmosphere surrounding the Pod through at least a portion of the aperture in the Pod being at least 0.01 linear feet/per minute for a clean room air flow of 70 ft/min, where the Pod is in an unobstructed location in the clean room, such as on a table.

Step 102 comprises flowing the surrounding air in the cleanroom through the aperture(s) into the storage Pod to expose the gas sensor to the surrounding air in the cleanroom for an exposure time. The air flow in the cleanroom alone can provide the driving force to flow the surrounding gases through the aperture into the storage Pod. The gas sensor in the storage Pod includes a suitable sensor material that generates a measurable response from exposure to the air in the cleanroom when the air in the cleanroom includes a target gas species. The response in one embodiment comprises forming a compound that includes target gas or a component thereof. In the embodiment the target is a halogen, the sensor materials can comprise a suitable metal or metal alloy coating that forms a compound upon exposure to the halogen, referred to as a “witness” wafer. The witness wafer has a coating which is sensitive to a halogen, such as shown in FIG. 3 described below. Airborne halogens, such as F₂, Cl₂, Br₂, I₂, are known to cause corrosion on metal leads of semiconductor devices, which can cause to yield loss.

Step 103 comprises determining a presence of the target gas in the clean room air around the storage Pod based on a detection signal from the gas sensor or evaluating at least one property of the gas sensor. In some embodiments the method further comprises removing the gas sensor from the storage Pod and then interrogating the gas sensor, such as when the gas sensor comprises a witness wafer. In the embodiment the gas sensor is removed from the storage Pod before interrogation, the exposure time during step 102 while the gas sensor is in the storage Pod is generally greater than the time between removal of the gas sensor from the storage Pod and interrogation. For example, the exposure time can be a plurality of hours, while the time between removal of the gas sensor from the storage Pod and interrogation can be less than one hour.

In one embodiment the gas sensor automatically generates a detection signal upon exposure to the target gas. In another embodiment, the property comprises color of the sensor material, where the sensor material provides a detectable change in color upon exposure to the target gas. The color change may be detected by an operator or by a machine. In another embodiment gas sensor comprises a witness wafer that is interrogated to generate a detection signal, where the interrogation can comprise optical or electrical interrogation.

Depending on the size of the detector system utilized, either the full detector system can be integrated within the storage Pod, or only the gas sensor and an optional wireless transmitter can be integrated within the Pod so that the sensor signals are evaluated outside the Pod by a remote computer or processor coupled to a wireless receiver for receiving the sensing signals. The processor can be configured to activate an alarm which can be activated when it is determined a target gas, such as a halogen, is present, or when the target gas is present above a predetermined concentration.

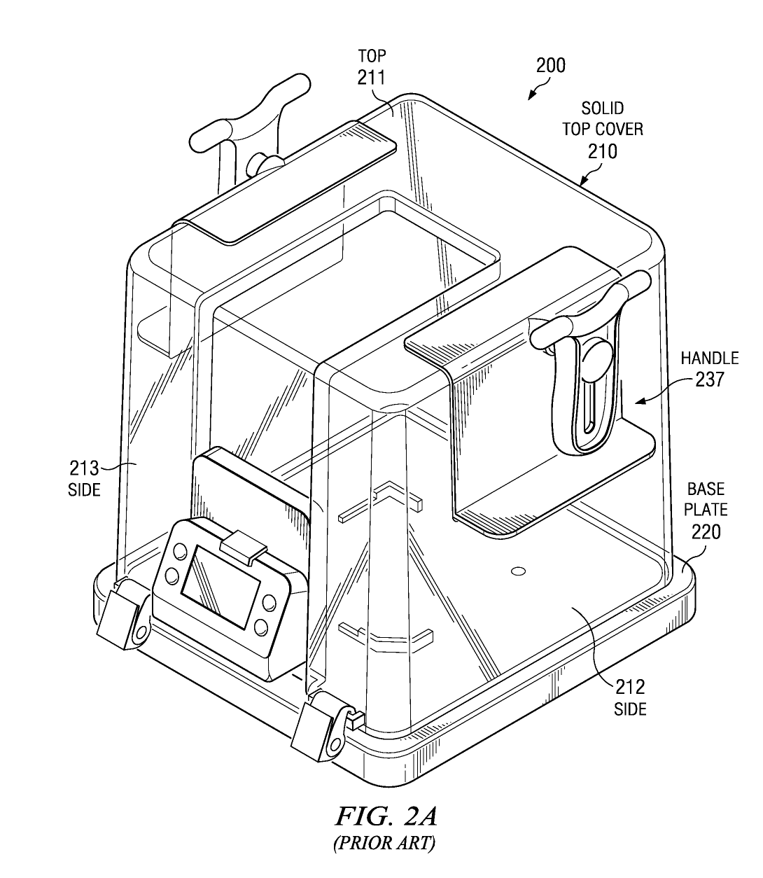

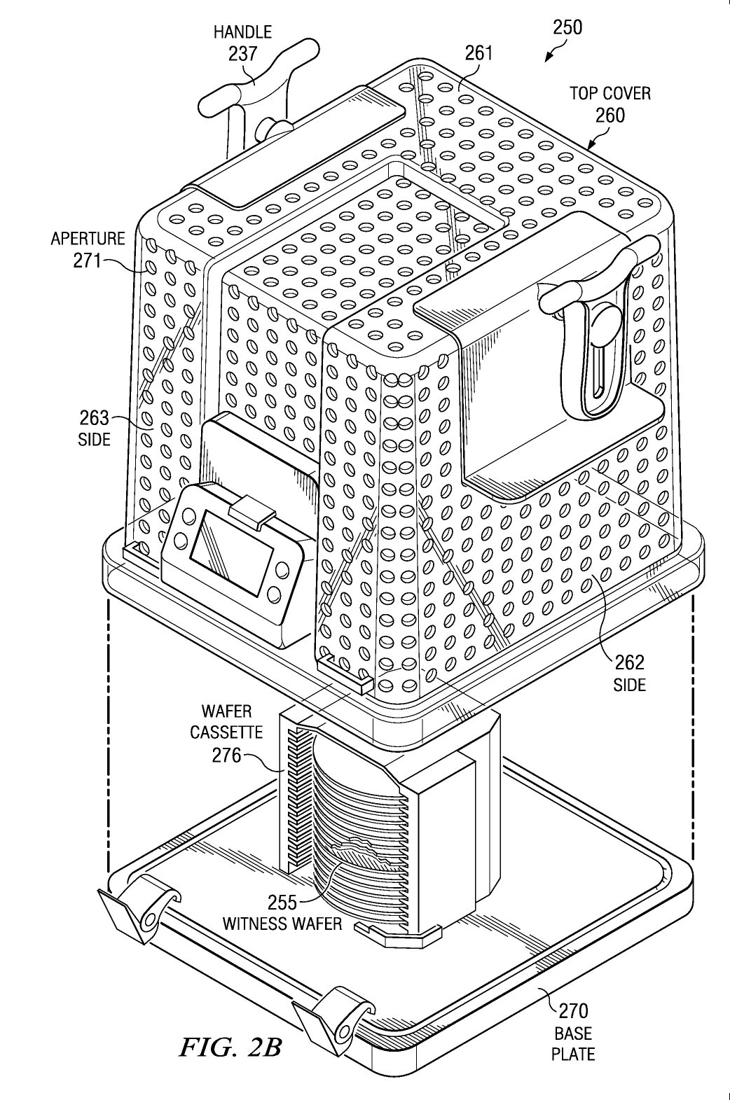

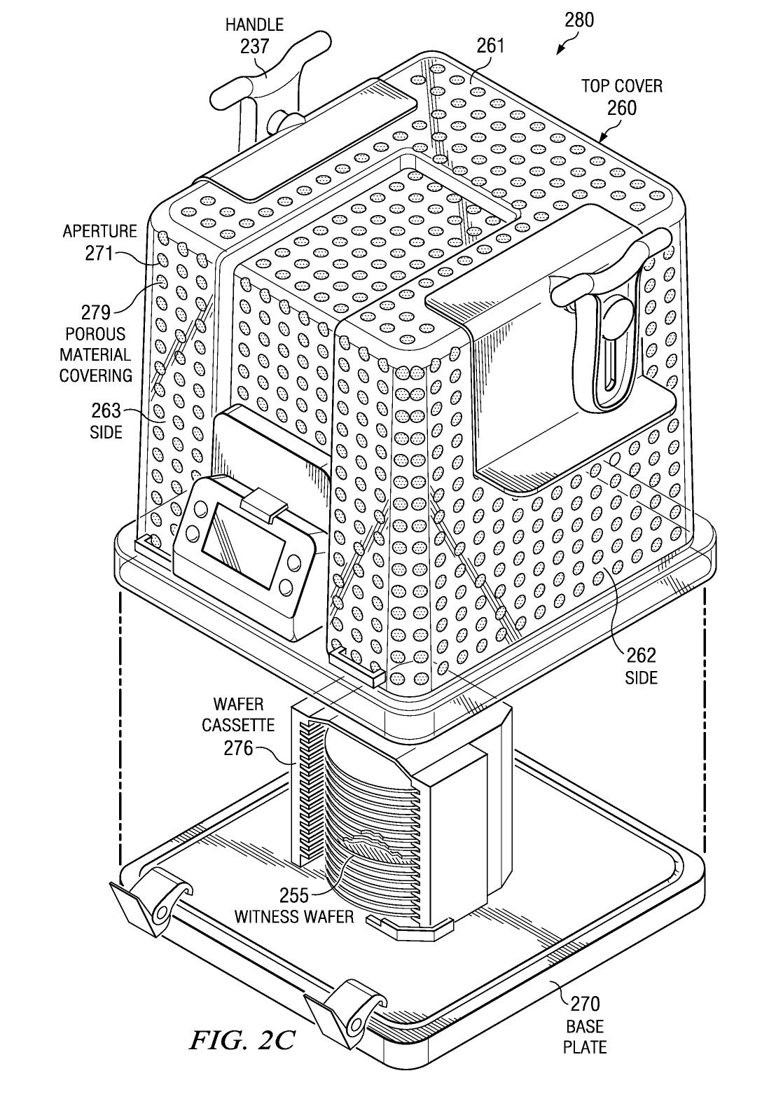

FIG. 2A is a depiction of a known storage Pod 200 for semiconductor substrates comprising a solid top cover 210 comprising a NAP material having faces including a top 211 and a plurality of sides including the sides 212 and 213 shown. The wafer cassette that is generally within the storage Pod 200 during operation is not shown to help reveal certain details of the Pod 200. Pod 200 includes a bottom base plate 220 having a locking structure configured for providing a locking position wherein the plurality of sides 212, 213 are locked to the bottom base plate 220, and for providing an unlocked position where the plurality of sides 212, 213 are detached from the bottom base plate 220. When in the locked position, storage Pod 200 is hermetically or nearly hermetically sealed, and functions to keep the fab environment isolated from the environment inside the Pod 200 including wafers therein. The handles 237 shown are for allowing operators to lift the Pod 200. For fully robot embodiments, handles 237 are not included.

FIG. 2B is a depiction of a storage Pod 250 for semiconductor substrates comprising a top cover 260 comprising a NAP material having faces including a top 261 and a plurality of sides shown as sides 262 and 263, wherein there are a plurality of apertures 271 in the NAP material of the top cover 260. The apertures 271 are shown as through-holes without any covering thereon to provide unobstructed through-holes. The plurality of apertures are spread across the plurality of sides 262, 263 and can be seen to be positioned periodically in all of the sides. The apertures 271 allow surrounding gases in an environment around the storage Pod to flow into the storage Pod 250.

Apertures 271 can be formed in a conventional solid top cover such as solid top cover 210 shown in FIG. 2A by drilling through-holes in the faces of the top cover 260 to form machined apertures. As shown a plurality of apertures 271 are positioned periodically in all of the faces of the storage Pod, wherein the plurality of apertures are circular shaped. Although storage Pod 250 is shown as a Standard Mechanical InterFace (SMIF), disclosed storage Pods can also comprise front opening unified Pods (FOUPs).

In the embodiment depicted in FIG. 2B, the apertures are drilled apertures ¼ inch in diameter with a ½ inch spacing between (center-to-center) each aperture 271. Storage Pod 250 sized to hold 200 mm wafers includes about 1,000 apertures 271.

Like known storage Pod 200, storage Pod 250 includes a bottom base plate 270 having a locking structure configured for providing a locking position wherein the plurality of sides of the top cover 262, 263 can be locked to the bottom base plate 270, and for providing an unlocked position where the plurality of sides 262, 263 of the top cover 260 are detached from the bottom base plate 270. There is a wafer cassette 276 shown sitting on the bottom base plate 270. The wafer cassette 276 is for holding semiconductor substrates (e.g., semiconductor wafers), and in the embodiment shown includes a gas sensor comprising a coated witness wafer 255 having a coating that is sensitive to the target gas in one of the slots of the wafer cassette 276.

In one particular embodiment the target gas can comprise at least one halogen and the coating can comprise a metal comprising coating. The sensor material for the coating may comprise any suitable material that generates a measurable response from exposure to a target gas species. Such sensor materials can comprise a suitable metal or metal alloy that demonstrate a detectable change in at least one property thereof upon contact with target gas, such as a fluorine or chlorine containing material. Many of the transition metals and noble metals including, for example, but not limited to, Ni, Cu, Ti, V, Cr, Mn, Nb, Mo, Ru, Pd, Ag, Ir, Al, and Pt, readily form various non-volatile fluorinated compounds in contact with fluorine and chlorine containing gaseous components and exhibit detectable changes, such as changes in light scattering or in electrical resistance, that may be used for the practice of disclosed embodiments.

In one embodiment the coating can provide a surface that changes its light scattering properties upon exposure to target gas to allow optical-based detection. The light source (e.g., laser) and the photodetector(s) can be positioned in the storage Pod, positioned outside the Pod, or partly positioned inside the Pod and partly positioned outside the Pod.

More generally, at least a gas sensor sensitive to at least one target gas of a gas detector system is within the storage Pod while gas sensing operations take place. For example, as disclosed above, the sensor can comprise electrical-based detection by providing a coating which provides a resistivity that is sensitive to exposure of a target gas. In this embodiment a power supply and resistivity measurement device/circuit can optionally also be positioned within the Pod.

FIG. 2C is depiction of a storage Pod 280 for semiconductor substrates comprising a top cover 260 comprising a NAP material having faces including a top 261 and a plurality of sides 262 and 263 shown, wherein there are a plurality of apertures 271 in the NAP material of the top cover 260. The apertures 271 are shown including porous material covering 279 for trapping particles that still allows at least one target gas in surrounding gases in the environment around the storage Pod to flow into the storage Pod 280.

FIG. 3 is a depiction of an example detector system 300 comprising a witness wafer 315 having a coating 311 thereon comprising a sensor material that generates a measurable optical response from exposure to a target gas species. It is noted that there are various types of coatings that can be used for witness wafers depending on purpose and sensitivity to various types of AMCs. Prior to disclosed embodiments a main challenge with the witness wafer sensing technique for sensing halogens was that the witness wafer needed to be directly exposed to the fab atmosphere, which required the cassette having the witness wafer to be removed from the Pod to sense the halogen, which became a difficult task for an automated fab that was equipped to only handle SMIF or FOUP.

A light source such as a laser 310 shown illuminates the witness wafer 315 with a laser beam at a given angle θ. A photodetector 316 is positioned to collect the reflected laser light. When present the halogen or other target gas reacts with the coating 311 on the witness wafer 315, so that the amount of reflected laser beam light detected by photodetector 316 will decrease due to increasing backscattered light. Electronic processing such as filtering and analog to digital conversion followed by digital signal processing provided by the processor 326 shown can be applied to the signal from the photodetector 316 to determine at what threshold is considered a problem, and then monitoring (e.g., triggering of an alarm) can be set for these levels.

Example embodiments are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

I claim:

1. A wafer cassette pod comprising:
A. a top cover having a top face and plural side faces, the top cover having apertures periodically spread across the top and side faces and the apertures extending through the material of the top cover; and
B. a base plate having a locking structure to lock the top cover to the base plate, the base plate including structure for carrying a semiconductor cassette on the base plate and within the top cover, the base plate being free of any through apertures.

2. The pod of claim 1 in which the apertures are about ¼ inch in diameter with about a ½ inch spacing between each aperture.

3. The pod of claim 1 in which the top cover is made of a non-air permeable material.

4. The pod of claim 1 in which the apertures provide a gas velocity from the atmosphere surrounding the pod through at least a portion of the apertures of at least 0.01 linear feet per minute for a clean room air flow of about 70 feet per minute, where the pod is in an unobstructed location in a clean room.

5. The pod of claim 1 in which the base and top are sized to contain a semiconductor cassette of 200 millimeter wafers and the top cover has about 1000 apertures.

6. The pod of claim 1 including porous material covering each aperture to trap particles while providing for flow of gas through the apertures.
